(19) United States
(12) Patent Application Publication
(10) Pub. No.: US 2005/0142461 A1
(43) Pub. Date: Jun. 30, 2005

(54) Photo mask and method for fabricating the same

(75) Inventor: Jun Seok Lee, Goyang (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/024,793

(22) Filed: Dec. 30, 2004

(30) Foreign Application Priority Data
Dec. 31, 2003 (KR) 10-2003-0101845

(51) Int. Cl. G03F 9/00; G03C 5/00

(52) U.S. Cl. 430/5; 430/322

(57) ABSTRACT

A photo mask and a method for fabricating the same are described, in which a transparent substrate is covered with a phase inversion light-transmitting layer, a plurality of small sized light-transmitting holes are aggregately formed at dense intervals in an isolated pattern hole region of the phase inversion light-transmitting layer, and lights transmitting the light-transmitting holes and the phase inversion light-transmitting layer are guided to cause a series of interference phenomena such as sidelobe phenomena, so that the isolated pattern hole can sufficiently receive lights as the light intensity increases by way of the sidelobe phenomena. If the sidelobe phenomena regarded as a defect factor are used to allow the isolated pattern hole to sufficiently receive lights after aggregately forming the small sized light-transmitting holes in the isolated pattern hole region of the transparent substrate, the step of additionally forming serif holes is naturally skipped, thereby improving yield of the product and controlling increase of the production cost.

### BACKGROUND OF THE INVENTION

1. Field of the Invention

The present invention relates to a photo mask for use in fabricating a semiconductor device, and more particularly, to a photo mask and a method for fabricating the same in which a transparent substrate is covered with a phase inversion light-transmitting layer, a plurality of small sized light-transmitting holes are aggregately formed at dense intervals in an isolated pattern hole region of the phase inversion light-transmitting layer. Light that is transmited through the light-transmitting holes and phase inversion light are guided to cause a series of interference phenomena such as sidelobe phenomena, so that the isolated pattern hole can sufficiently receive sufficient light intensity in all portions thereof, including a center portion, (by way of the sidelobe phenomena) to create a via hole with excellent height to depth aspect ratio.

2. Discussion of the Related Art

Recently, as semiconductor devices become more highly integrated, respective structures constituting a semiconductor device have increasingly fine geometrical structures. Thus, photo masks for patterning corresponding structures have undergone various structures in an attempt to keep up with the small feature size demands of modern semiconductor devices.

A photo mask 10 for fabricating a semiconductor device according to the related art, as shown in FIG. 1, includes a transparent substrate 4, light-shielding layers 5 formed on the transparent substrate 4 and separated from one another, and light-transmitting holes 6 and 7 formed by opening the light-shielding layers 5. In this structure, if a light emitted from a light source 100 is irradiated into a pattern structure 2 on a semiconductor substrate 1 through the light-transmitting holes 6 and 7, a residual image corresponding to shapes of the light-transmitting holes 6 and 7 may naturally be formed in the corresponding pattern structure 2. Afterwards, if a series of process steps are finished, a series of pattern holes H1 and H2 corresponding to the residual image can be formed in the corresponding structure 2.

At this time, it is necessary that some pattern holes, such as pattern hole H2, be formed in isolation in a portion of the semiconductor substrate 1 depending on unique characteristics of the pattern structure 2, unlike the other pattern holes H1, which are formed adjacent to one another. In the related art considering such an isolated pattern hole H2, as shown in FIG. 2, a method for forming an isolated light-transmitting hole 7 spaced apart from the light-transmitting holes 6 in a portion of the photo mask 10 has been suggested.

Under the related art photo mask system, it is conventional for light used to form aggregated pattern holes H1 be transmited via aggregated light-transmitting holes 6. Such light has a light intensity distribution greater than that of light used to form the isolated pattern hole H2 by transmitting the isolated light-transmitting hole 7, due to an interactive accelerating action.

Under the condition that light transmited via the aggregated light-transmitting holes 6 has a light intensity distribution greater than that of light transmited through the isolated light-transmitting hole 7, a series of patterning processes of structures may be performed without any separate step because the aggregated pattern holes H1 can receive lights having sufficient light intensity required for themselves without any difficulty. Thus, the aggregated pattern holes H1 can naturally have normal shapes with sufficiently good aspect ratios when a series of process steps are finished. Unlike the aggregated pattern holes H1, the isolated pattern hole H2 cannot receive light having sufficient light intensity required for itself. Thus, the isolated pattern hole H2 cannot have a normal shape (e.g., poor aspect ratio) when a series of process steps are finished. Finally, the completed semiconductor device has deteriorated quality.

In the related art considering such a defect of the isolated pattern hole H2, as shown in FIG. 2, a series of serif holes 7a are additionally formed in the vicinity of the isolated light-transmitting hole 7 and the quantity of light emitted to the isolated pattern hole H2 through the serif holes 7a is maximized, so that the isolated pattern hole H2 can receive lights having improved intensity.

However, as recognized by the present inventor, even in case that the serif holes 7a are additionally formed in the vicinity of the isolated light-transmitting hole 7, since differences in light intensity distribution basically exists between the aggregated light-transmitting holes 6 and the isolated light-transmitting hole 7, it is difficult for the isolated pattern hole to receive sufficient light. Moreover, since complicated process steps are required to additionally form the serif holes 7a, yield of the product may greatly be reduced and the production cost may increase rapidly.

### SUMMARY OF THE INVENTION

Accordingly, the present invention is directed to a photo mask and a method for fabricating the same that substantially obviates one or more of the above-identified and other problems due to limitations and disadvantages of the related art.

An object of the present invention is to provide a photo mask and a method for fabricating the same in which a transparent substrate is covered with a phase inversion light-transmitting layer, a plurality of small sized light-transmitting holes are aggregately formed at dense intervals in an isolated pattern hole region of the phase inversion light-transmitting layer, and light transmited through the light-transmitting holes and the phase inversion light transmitted through the transmitting layer are guided to cause a series of interference phenomena such as sidelobe phenomena, so that the isolated pattern hole can sufficiently receive lights as the light intensity increases by way of the sidelobe phenomena.

Another object of the present invention is to provide a photo mask and a method for fabricating the same in which sidelobe phenomena regarded as a defect factor are used to allow an isolated pattern hole to sufficiently receive lights after aggregately forming small sized light-transmitting holes in an isolated pattern hole region of a transparent substrate, so that the step of additionally forming serif holes is naturally skipped, thereby improving yield of the product and controlling increase of the production cost.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a photo mask includes a transparent substrate, a phase inversion light-transmitting layer covering the entire surface of the transparent substrate, and a plurality of small sized light-transmitting holes aggregately formed at dense intervals at a predetermined region of the phase inversion light-transmitting layer.

In another aspect, a method for fabricating a photo mask includes forming a phase inversion light-transmitting layer on the entire surface of a transparent substrate, and forming a plurality of small sized light-transmitting holes aggregately formed at dense intervals at a predetermined region of the phase inversion light-transmitting layer by patterning the phase inversion light-transmitting layer.

The present inventor recognized that if the light energy from sidelobes, which is conventionally thought to be an unwanted effect, can be properly combined with sidelobes from light passing though adjacent holes, the desirable effect of providing high intensity at predetermined locations on the imaging area can be achieved by adding sidelobe energy that is in phase (or constructive adds).

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 and FIG. 2 are exemplary views illustrating a photo mask according to the related art;

FIG. 3 and FIG. 4 are exemplary views illustrating a photo mask according to the present invention;

FIG. 5A and FIG. 5B are exemplary views illustrating an enlarged isolated light-transmitting hole according to one embodiment of the present invention;

FIG. 6 is a graph illustrating variation in amplitude and intensity of lights transmitted through a first region of a photo mask according to the present invention;

FIG. 7A to FIG. 7D are graphs illustrating variation in amplitude and intensity of lights transmitting a second region of a photo mask according to the present invention;

FIG. 8A and FIG. 8B are exemplary views illustrating process steps of forming an isolated pattern hole according to one embodiment of the present invention;

FIG. 9A and FIG. 9B are exemplary views illustrating process steps of fabricating a photo mask according to one embodiment of the present invention;

FIG. 10 and FIG. 11 are exemplary views illustrating an enlarged isolated light-transmitting hole according to other embodiment of the present invention; and

FIG. 12A and FIG. 12D are exemplary views illustrating process steps of fabricating a photo mask according to another embodiment of the present invention.

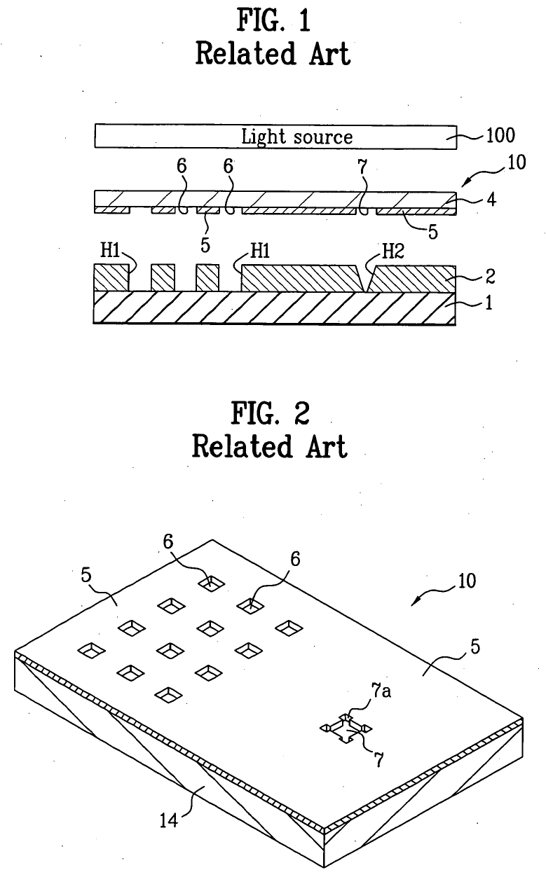

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a photo mask and a method for fabricating the same according to the present invention will be described as follows.

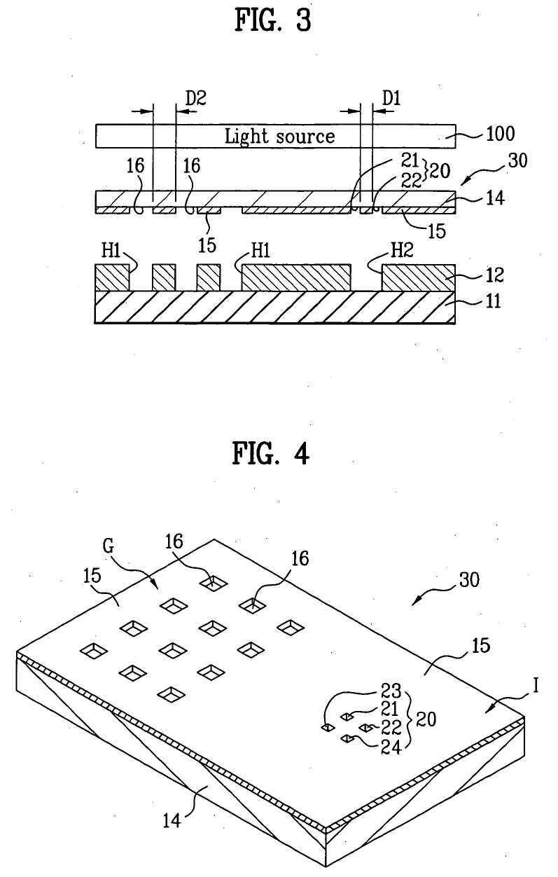

As shown in FIG. 3 and FIG. 4, a photo mask 30 of the present invention includes a transparent substrate 14, a phase inversion light-transmitting layer 15 covering the entire surface of the transparent substrate 14, and a plurality of light-transmitting holes 16 and 20 formed by opening the phase inversion light-transmitting layer 15. In this case, a glass substrate or a quartz substrate may optionally be used as the transparent substrate 14. Preferably, an attenuated type phase inversion light-transmitting layer may be used as the phase light-transmitting layer 15.

In this state, if a series of lights (or simply “light”) emitted from a light source 100 are irradiated into a pattern structure 12 on a semiconductor substrate 11 through the light-transmitting holes 16 and 20, residual images corresponding to shapes of the light-transmitting holes 16 and 20 may naturally be formed in the corresponding pattern structure 12. Afterwards, if a series of process steps are finished, a series of pattern holes H1 and H2 corresponding to the residual images can be formed in the corresponding pattern structure 12.

Inevitably, some pattern holes, such as hole H2, are formed in isolation in a portion of the semiconductor substrate 11 depending on unique characteristics of the pattern structure 12, unlike the other pattern holes H1. In the present invention considering such an isolated pattern hole H2, as shown, a method for forming an isolated light-transmitting hole 20 spaced apart from the light-transmitting holes 16 of a group pattern hole region G in an isolated pattern hole region I of the phase inversion light-transmitting layer 15 has been suggested.

Under the photo mask system, it is conventional that light used to form aggregated pattern holes H1 by transmitting aggregated light-transmitting holes 16 have a light intensity distribution greater than that of light used to form the isolated pattern hole H2 by transmitting the isolated light-transmitting hole 20, due to an interactive accelerating action.

Under the condition that light transmitted through the aggregated light-transmitting holes 16 have a light intensity distribution greater than that of light transmitting through the isolated light-transmitting hole 20, if a series of patterning processes of structures are performed without any separate step, the aggregated pattern holes H1 can receive light having sufficient intensity required for themselves without any difficulty. Thus, the aggregated pattern holes H1 can naturally have normal shapes when a series of process steps are finished. Unlike the aggregated pattern holes H1, the isolated pattern hole H2 cannot receive light having sufficient intensity required for itself. Thus, the isolated pattern hole H2 cannot create a normal shape in the pattern 12 when a series of process steps are finished. Consequently, the completed semiconductor device has deteriorated quality.

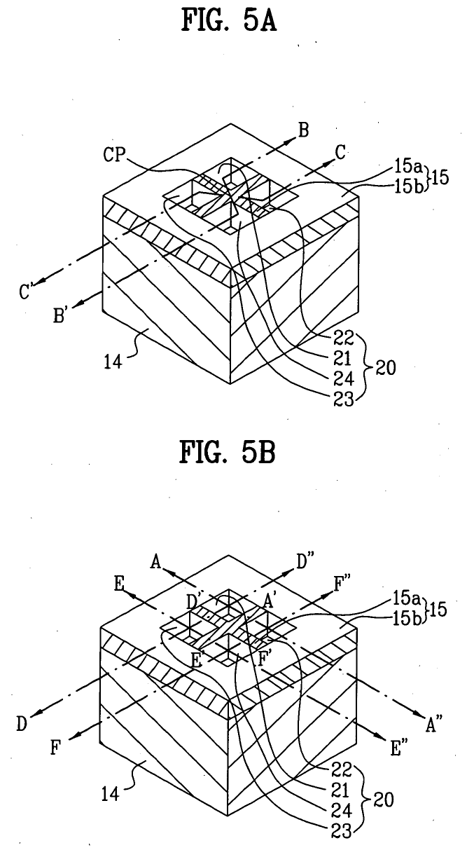

In the present invention considering such a defect of the isolated pattern hole H2, as shown in FIGS. 5A and 5B (as well as FIG. 4), the isolated light-transmitting hole 20 includes a plurality of small sized light-transmitting holes 21, 22, 23 and 24 aggregately formed at dense intervals. The number of the small sized light-transmitting holes may be varied depending on circumstances. For example the number of holes may be 2, 3, 4, 5, 6, 7, 8, 9 or 10 as examples.

At this time, the light-transmitting holes 21, 22, 23 and 24 are spaced apart from one another at uniform intervals using the phase inversion light-transmitting layer 15 as a barrier wall. Preferably, the light-transmitting holes 21, 22, 23 and 24 have a size of 0.02 μm to 0.06 μm. In this case, the phase inversion light-transmitting layer 15a arranged between the respective light-transmitting holes 21, 22, 23 and 24 and the phase inversion light-transmitting layer 15b arranged outside the light-transmitting holes 21, 22, 23 and 24 have a light-transmitting ratio of 3% to 12%, preferably.

If the small sized light-transmitting holes 21, 22, 23 and 24 are aggregately formed at dense intervals in an isolated pattern hole region I (FIG. 4) of the phase inversion light-transmitting layer 15 using the phase inversion light-transmitting layer 15a as a barrier wall, light transmitted through the light-transmitting holes 21, 22, 23 and 24 and the phase inversion light-transmitting layer 15a are guided to cause a series of interactive interference phenomena such as sidelobe phenomena. Thus, the isolated pattern hole H2 can receive sufficient light throughout the desired target area (e.g., pattern 12) to create a feature with the intended aspect ratio by way of the sidelobe phenomena. Moreover, not only is the light intensity at the pattern 12 increased, it is increased in a controlled way such that the light intensity creates a features in the pattern 12 with a desired shape and depth.

If the sidelobe phenomena, which is conventionally regarded as a defect factor, is used to allow an isolated pattern hole H2 to sufficiently receive light after aggregately forming the small sized light-transmitting holes 21, 22, 23 and 24 in the isolated pattern hole region I of the transparent substrate 14, the step of additionally forming serif holes is naturally skipped, thereby improving yield of the product and controlling increase of the production cost.

The process steps of forming the isolated pattern hole H2 based on the sidelobe phenomena will be described in more detail with reference to the distribution of the light intensity between the respective light-transmitting holes 21, 22, 23 and 24.

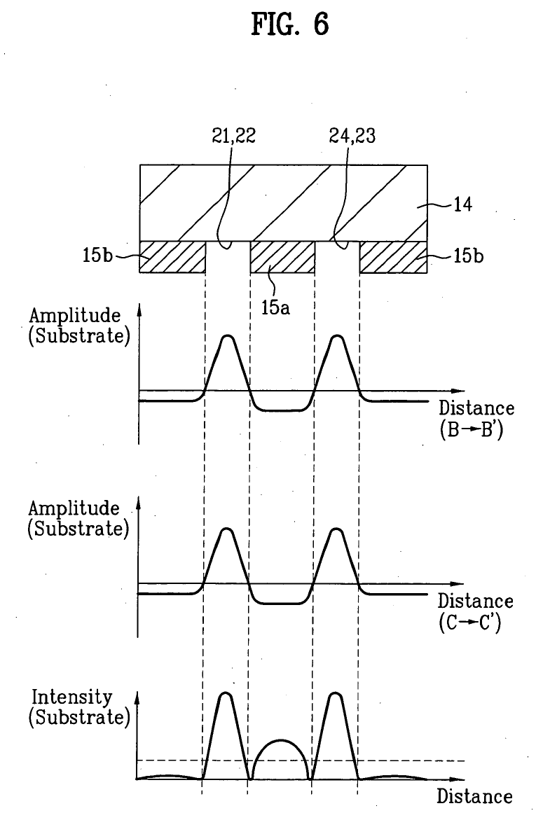

When viewed from the section taken along line B-B′ of FIG. 5A, lights which have transmitted the small sized light-transmitting holes 21 and 24 divided by the phase inversion light-transmitting layer 15a within the range of 100% have a positive (+) phase (meaning a phase that would allow the light to add constructively with a reference light), lights which have transmitted the phase inversion light-transmitting layer 15b arranged outside the small sized light-transmitting holes 21 and 24 within the range of 3% to 12% have a negative (−) phase (meaning that the amplitude of the light would add destructively to the reference light), and lights which have transmitted the phase inversion light-transmitting layer 15a arranged between the small sized light-transmitting holes 21 and 24 within the range of 3% to 12% have a negative (−) phase, as will be evident from FIG. 6. FIG. 6 shows the amplitude of the light over the image area, where the respective zero crossing shows a change of phase of the light. For instance light from area 15b has an opposite phase as light that passes through holes 21,22 and 24,23.

Further, when viewed from the section taken along line C-C′ of FIG. 5A, lights which have transmitted the small sized light-transmitting holes 22 and 23 divided by the phase inversion light-transmitting layer 15a within the range of 100% have a positive (+) phase, lights which have transmitted the phase inversion light-transmitting layer 15b arranged outside the small sized light-transmitting holes 22 and 23 within the range of 3% to 12% have a negative (−) phase, and lights which have transmitted the phase inversion light-transmitting layer 15a arranged between the small sized light-transmitting holes 22 and 23 within the range of 3% to 12% have a negative (−) amplitude, as will be evident from FIG. 6.

When viewed from the sections taken along line B-B′ of FIG. 5A and line C-C′ of FIG. 5B optically overlapped, the amplitude of the lights which have transmitted through the light-transmitting holes 21 and 24 do not overlap in phase the lights which have transmitted through the light-transmitting holes 22 and 23. Therefore, additional variation in the light intensity other than that corresponding to self-amplitude does not occur on the semiconductor substrate 11 (pattern structure).

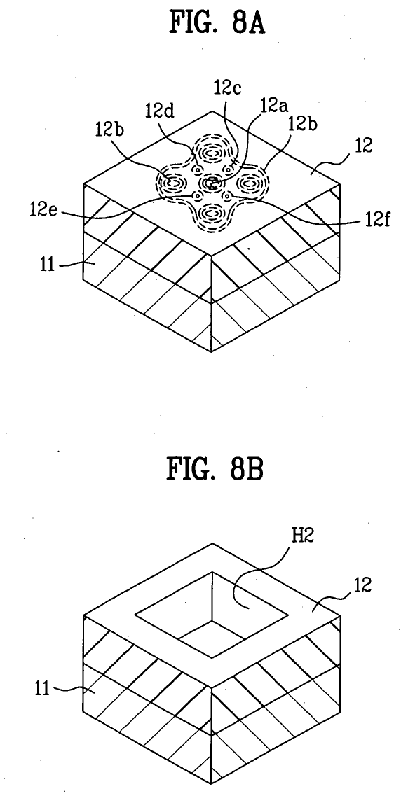

However, the amplitudes of the lights which have transmitted the phase inversion light-transmitting layer 15a arranged between the respective light-transmitting holes 21, 22, 23 and 24, that is, the amplitudes of the lights which have transmitted a common point CP are overlap each other and thus reinforce one another. In this case, a series of sidelobe phenomena strongly occur on the semiconductor substrate, so that the light intensity may increase at a certain range or greater. Finally, as shown in FIG. 8A, a residual image 12a caused by the sidelobe phenomena other than a regular residual image 12b caused by the light-transmitting holes 21, 22, 23 and 24 can quickly be formed on the pattern structure 12.

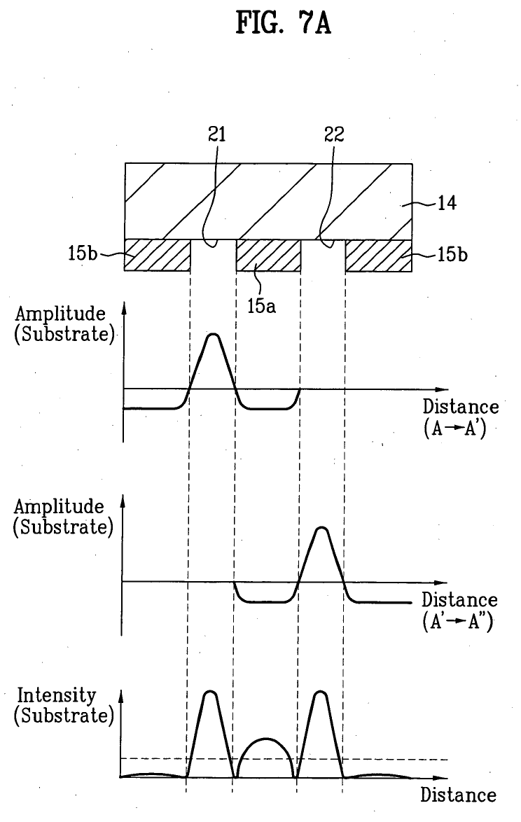

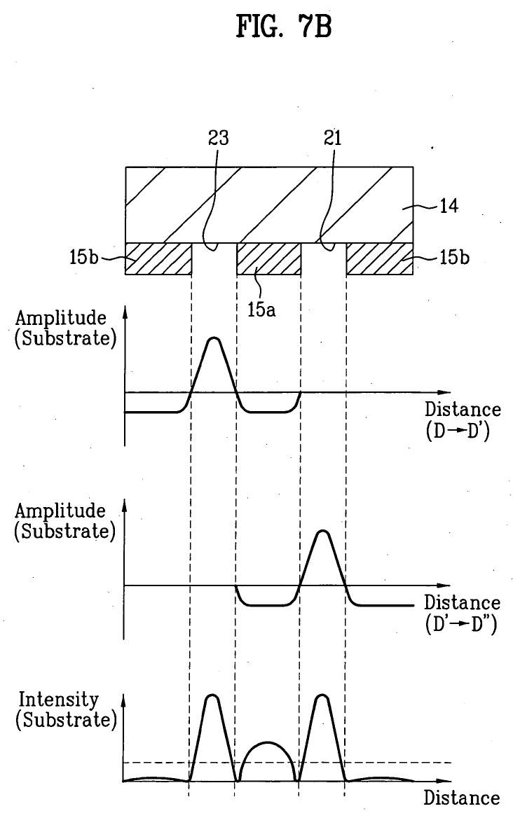

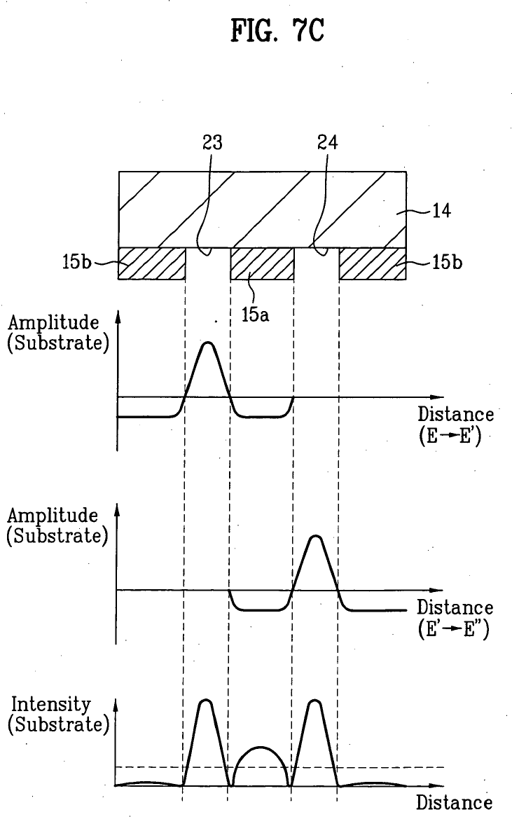

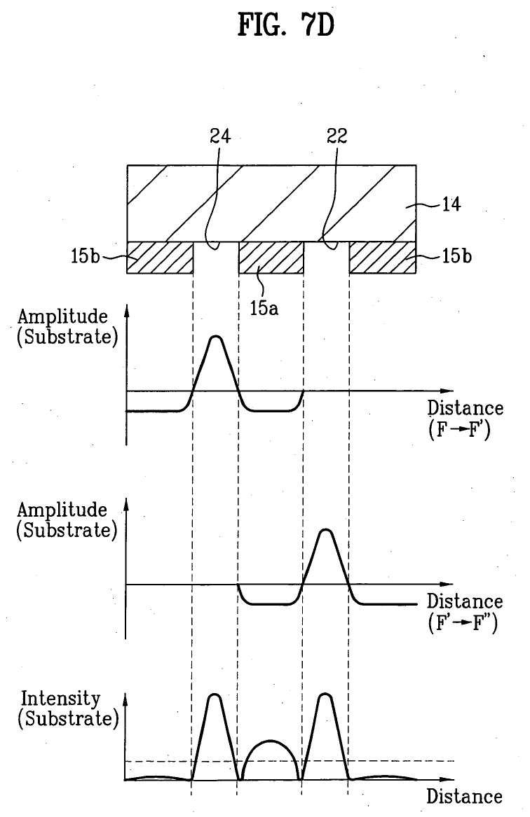

When viewed from the section taken along line A-A′ of FIG. 5B, lights which have transmitted the small sized light-transmitting hole 21 divided by the phase inversion light-transmitting layer 15a within the range of 100% have a positive (+) phase, lights which have transmitted the phase inversion light-transmitting layer 15b arranged outside the small sized light-transmitting hole 21 within the range of 3% to 12% have a negative (−) phase, and lights which have transmitted the phase inversion light-transmitting layer 15a arranged between the small sized light-transmitting holes 21 and 22 within the range of 3% to 12% have a negative (−) phase, as will be evident from FIG. 7A.

Further, when viewed from the section taken along line A′-A″ of FIG. 5B, lights which have transmitted the small sized light-transmitting hole 22 divided by the phase inversion light-transmitting layer 15a within the range of 100% have a positive (+) phase, lights which have transmitted the phase inversion light-transmitting layer 15b arranged outside the small sized light-transmitting hole 22 within the range of 3% to 12% have a negative (−) phase, and lights which have transmitted the phase inversion light-transmitting layer 15a arranged between the small sized light-transmitting holes 21 and 22 within the range of 3% to 12% have a negative (−) phase, as will be evident from FIG. 7A.

When viewed from the sections taken along line A-A′ of FIG. 5B and line A′-A″ of FIG. 5B optically overlapped, the amplitude of the lights which have transmitted the light-transmitting hole 21 do not overlap the amplitude of the lights which have transmitted the light-transmitting hole 22. Therefore, additional variation in the light intensity other than that corresponding to self-amplitude does not occur on the semiconductor substrate 11 (pattern structure).

However, the amplitudes of the lights which have transmitted the phase inversion light-transmitting layer 15a arranged between the respective light-transmitting holes 21 and 22, that is, the amplitudes of the lights which have transmitted a common point A′ are overlap and therefore reinforce each other. In this case, a series of sidelobe phenomena strongly occur on the semiconductor substrate 11, so that the light intensity may increase at a certain range or greater. Finally, as shown in FIG. 8A, a residual image 12a caused by the sidelobe phenomena other than a regular residual image 12b caused by the light-transmitting holes 21 and 22 can quickly be formed on the pattern structure 12.

Subsequently, when viewed from the section taken along line D-D′ of FIG. 5B, lights which have transmitted the small sized light-transmitting hole 23 divided by the phase inversion light-transmitting layer 15a within the range of 100% have a positive (+) phase, lights which have transmitted the phase inversion light-transmitting layer 15b arranged outside the small sized light-transmitting hole 23 within the range of 3% to 12% have a negative (−) phase, and lights which have transmitted the phase inversion light-transmitting layer 15a arranged between the small sized light-transmitting holes 21 and 23 within the range of 3% to 12% have a negative (−) phase, as will be evident from FIG. 7B.

Further, when viewed from the section taken along line D′-D″ of FIG. 5B, lights which have transmitted the small sized light-transmitting hole 21 divided by the phase inversion light-transmitting layer 15a within the range of 100% have a positive (+) phase, lights which have transmitted the phase inversion light-transmitting layer 15b arranged outside the small sized light-transmitting hole 21 within the range of 3% to 12% have a negative (−) phase, and lights which have transmitted the phase inversion light-transmitting layer 15a arranged between the small sized light-transmitting holes 21 and 23 within the range of 3% to 12% have a negative (−) phase, as will be evident from FIG. 7B.

When viewed from the sections taken along line D-D′ of FIG. 5B and line D′-D″ of FIG. 5B optically overlapped, the amplitude of the lights which have transmitted the light-transmitting hole 23 do not overlap the amplitude of the lights which have transmitted the light-transmitting hole 21. Therefore, additional variation in the light intensity other than that corresponding to self-amplitude does not occur on the semiconductor substrate 11 (pattern structure).

However, the amplitudes of the lights which have transmitted the phase inversion light-transmitting layer 15a arranged between the respective light-transmitting holes 21 and 23, that is, the amplitudes of the lights which have transmitted a common point D′ are overlapped with each other. In this case, a series of sidelobe phenomena strongly occur on the semiconductor substrate 11, so that the light intensity may increase at a certain range or greater. Finally, as shown in FIG. 8A, a residual image 12d caused by the sidelobe phenomena other than a regular residual image 12b caused by the light-transmitting holes 21 and 23 can quickly be formed on the pattern structure 12.

Next, when viewed from the section taken along line E-E′ of FIG. 5B, lights which have transmitted the small sized light-transmitting hole 23 divided by the phase inversion light-transmitting layer 15a within the range of 100% have a positive (+) phase, lights which have transmitted the phase inversion light-transmitting layer 15b arranged outside the small sized light-transmitting hole 23 within the range of 3% to 12% have a negative (−) phase, and lights which have transmitted the phase inversion light-transmitting layer 15a arranged between the small sized light-transmitting holes 23 and 24 within the range of 3% to 12% have a negative (−) phase, as will be aware of it from FIG. 7C.

Further, when viewed from the section taken along line E′-E″ of FIG. 5B, lights which have transmitted the small sized light-transmitting hole 24 divided by the phase inversion light-transmitting layer 15a within the range of 100% have a positive (+) phase, lights which have transmitted the phase inversion light-transmitting layer 15b arranged outside the small sized light-transmitting hole 24 within the range of 3% to 12% have a negative (−) phase, and lights which have transmitted the phase inversion light-transmitting layer 15a arranged between the small sized light-transmitting holes 23 and 24 within the range of 3% to 12% have a negative (−) phase, as will be aware of it from FIG. 7C.

When viewed from the sections taken along line E-E′ of FIG. 5B and line E′-E″ of FIG. 5B optically overlapped, the amplitude of the lights which have transmitted the light-transmitting hole 23 do not overlap the amplitude of the lights which have transmitted the light-transmitting hole 24. Therefore, additional variation in the light intensity other than that corresponding to self-amplitude does not occur on the semiconductor substrate 11 (pattern structure).

However, the amplitudes of the lights which have transmitted the phase inversion light-transmitting layer 15a arranged between the respective light-transmitting holes 23 and 24, that is, the amplitudes of the lights which have transmitted a common point E′ are overlapped with each other. In this case, a series of sidelobe phenomena strongly occur on the semiconductor substrate 11, so that the light intensity may increase at a certain range or greater. Finally, as shown in FIG. 8A, a residual image 12e caused by the sidelobe phenomena other than a regular residual image 12b caused by the light-transmitting holes 23 and 24 can quickly be formed on the pattern structure 12.

Besides, when viewed from the section taken along line F-F′ of FIG. 5B, lights which have transmitted the small sized light-transmitting hole 24 divided by the phase inversion light-transmitting layer 15a within the range of 100% have a positive (+) phase, lights which have transmitted the phase inversion light-transmitting layer 15b arranged outside the small sized light-transmitting hole 24 within the range of 3% to 12% have a negative (−) phase, and lights which have transmitted the phase inversion light-transmitting layer 15a arranged between the small sized light-transmitting holes 22 and 24 within the range of 3% to 12% have a negative (−) phase, as will be evident from FIG. 7D.

Further, when viewed from the section taken along line F′-F″ of FIG. 5B, lights which have transmitted the small sized light-transmitting hole 22 divided by the phase inversion light-transmitting layer 15a within the range of 100% have a positive (+) phase, lights which have transmitted the phase inversion light-transmitting layer 15b arranged outside the small sized light-transmitting hole 22 within the range of 3% to 12% have a negative (−) phase, and lights which have transmitted the phase inversion light-transmitting layer 15a arranged between the small sized light-transmitting holes 22 and 24 within the range of 3% to 12% have a negative (−) phase, as will be evident from FIG. 7D.

When viewed from the sections taken along line F-F′ of FIG. 5B and line F′-F″ of FIG. 5B optically overlapped, the amplitude of the lights which have transmitted the light-transmitting hole 22 does not overlap the amplitude of the lights which have transmitted the light-transmitting hole 24. Therefore, additional variation in the light intensity other than that corresponding to self-amplitude does not occur on the semiconductor substrate 11 (pattern structure).

However, the amplitudes of the lights which have transmitted the phase inversion light-transmitting layer 15a arranged between the respective light-transmitting holes 22 and 24, that is, the amplitudes of the lights which have transmitted a common point F′ are overlapped with each other. In this case, a series of sidelobe phenomena strongly occur on the semiconductor substrate 11, so that the light intensity may increase at a certain range or greater. Finally, as shown in FIG. 8A, a residual image 12f caused by the sidelobe phenomena other than a regular residual image 12b caused by the light-transmitting holes 22 and 24 can quickly be formed on the pattern structure 12.

Under the condition that the respective residual images are formed, if a series of process steps are finished, as shown in FIG. 8B, an isolated pattern hole H2 having a normal shape substantially equal to shapes of the aggregated pattern holes H1 can be formed in the pattern structure 12. It is noted that the sidelobe phenomena regarded as a defect factor has been greatly served to form the normalized isolated pattern hole H2.

Meanwhile, as shown in FIG. 3 and FIG. 4, the respective light-transmitting holes 16 arranged in the group pattern hole region G are divided using the phase inversion light-transmitting layer 15 as a barrier wall, like the isolated light-transmitting hole 20 arranged in the isolated pattern hole region I. In this case, there may be a question that a series of sidelobe phenomena may occur in the light-transmitting holes 16. Such sidelobe phenomena may adversely affect the formation of the aggregated pattern holes H1, unlike the case of the isolated pattern hole H2.

However, since the width D2 of the faces of the inversion light-transmitting layer 15 constituting the barrier wall of the respective light-transmitting holes 16 is wider than the width D1 of the phase inversion light-transmitting layer 15a constituting the barrier wall of the isolated light-transmitting hole 20, i.e., the light-transmitting holes 21, 22, 23 and 24, the light-transmitting holes 16 have dense intervals less than those of the light-transmitting holes 21, 22, 23 and 24. Therefore, even in case that the respective light-transmitting holes 16 arranged in the group pattern hole region G have a structure divided by the phase inversion light-transmitting layer 15 like the isolated light-transmitting hole 20 arranged in the isolated pattern hole region I, the corresponding light-transmitting holes 16 can avoid an adverse effect caused by the excessive sidelobe phenomena.

A method for fabricating a photo mask according to one embodiment of the present invention will now be described in more detail.

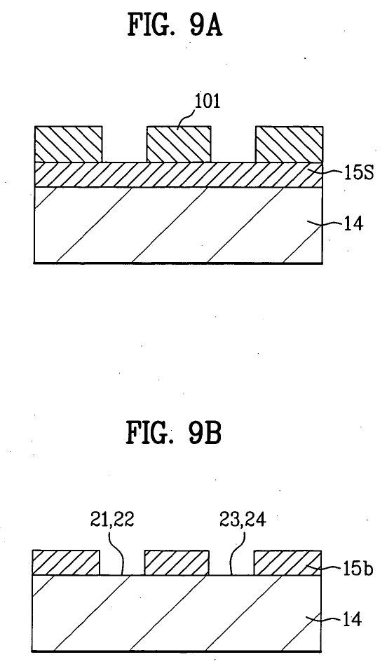

As shown in FIG. 9A, a Cr layer 15s to be used as a phase inversion light-transmitting layer is formed on a transparent substrate 14 such as a quartz substrate by a chemical vapor deposition process. In this case, the Cr layer 15s has a light-transmitting ratio of 3% to 12%.

Subsequently, a photoresist film is deposited on the Cr layer 15s and then is selectively etched to form a photoresist pattern 101 corresponding to regions for the small sized light-transmitting holes 21, 22, 23 and 24.

Next, the Cr layer 15s is dry-etched using the photoresist pattern 101 as an etching mask to expose some of the surface of the transparent substrate 14. Thus, as shown in FIG. 9B, the small sized light-transmitting holes 21, 22, 23 and 24 aggregated at dense intervals are formed in the isolated pattern hole region I of the phase inversion light-transmitting layers 15a and 15b. Then, the process steps of fabricating a photo mask are completed. Although not shown, it should be understood that the light-transmitting holes 16 can simultaneously be formed in the group pattern hole region G of the phase inversion light-transmitting layer 15 within the range of the procedure of forming the small sized light-transmitting holes 21, 22, 23 and 24.

Meanwhile, in the embodiment of the present invention, if the light-transmitting ratio of the phase inversion light-transmitting layer 15a arranged between the respective light-transmitting holes 21, 22, 23 and 24 is determined as a maximum value, the sidelobe phenomena caused by lights which have transmitted the corresponding phase inversion light-transmitting layer 15a may be generated more strongly in proportion to increase of the light-transmitting ratio of the phase light-transmitting layer 15a. Finally, in the present invention, the isolated pattern hole H2 may be formed more easily.

However, as described above, the phase inversion light-transmitting layer 15a arranged between the respective light-transmitting holes 21, 22, 23 and 24 has the same light-transmitting ratio of 3% to 12% as that of the phase inversion light-transmitting layer 15b arranged outside the light-transmitting holes 21, 22, 23 and 24. Therefore, if the light-transmitting ratio of the phase inversion light-transmitting layer 15a arranged between the respective light-transmitting holes 21, 22, 23 and 24 increases without any separate step, the light-transmitting ratio of the phase inversion light-transmitting layer 15b arranged outside the light-transmitting holes 21, 22, 23 and 24 also increases unnecessarily. The respective light-transmitting holes 16 of the group pattern hole region G divided by the phase light-transmitting layer 15b may be affected like the isolated light-transmitting hole 20. As a result, there may be a problem that quality of the whole pattern holes is deteriorated due to increase of unnecessary sidelobe energy.

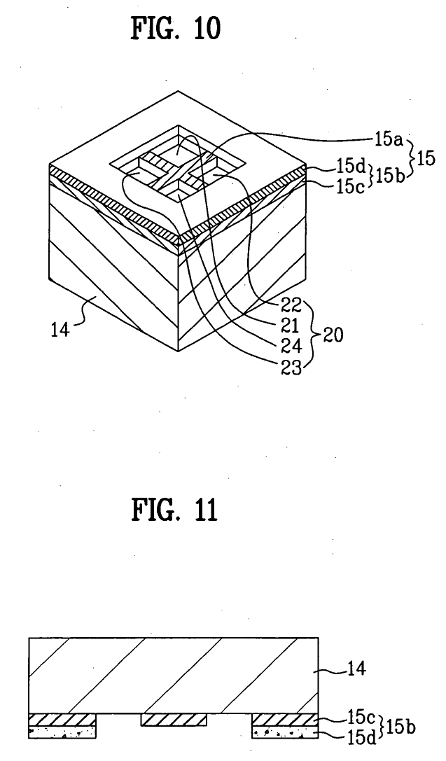

In another embodiment of the present invention considering such a problem, as shown in FIG. 10 and FIG. 11, the phase inversion light-transmitting layer 15a arranged between the respective light-transmitting holes 21, 22, 23 and 24 is formed of a single layered structure of Cr. Also, the phase inversion light-transmitting layer 15b arranged outside the light-transmitting holes 21, 22, 23 and 24 is formed of multi-layered structures 15c and 15d such as Cr/MoSiN, Cr/Si₃N₄, and Cr/SiO₂. Thus, the phase inversion light-transmitting layer 15a arranged between the respective light-transmitting holes 21, 22, 23 and 24 has a light-transmitting ratio greater than that of the phase inversion light-transmitting layer 15b arranged outside the light-transmitting holes 21, 22, 23 and 24.

In this case, the phase inversion light-transmitting layer 15a arranged between the respective light-transmitting holes 21, 22, 23 and 24 has a light-transmitting ratio of 5% to 12% while the phase inversion light-transmitting layer 15b arranged outside the light-transmitting holes 21, 22, 23 and 24 has a light-transmitting ratio of 3% to 7%.

As described above, the sidelobe phenomena caused by lights which have transmitted the corresponding phase inversion light-transmitting layer 15a having an optimal light-transmitting ratio may be generated more strongly in proportion to increase of the light-transmitting ratio of the phase light-transmitting layer 15a. Finally, the isolated pattern hole H2 may be formed more easily than the first embodiment.

In yet another embodiment of the present invention, the phase inversion light-transmitting layer 15b arranged outside the light-transmitting holes 21, 22, 23 and 24 has a light-transmitting ratio different from that of the phase inversion light-transmitting layer 15a arranged between the respective light-transmitting holes 21, 22, 23 and 24. Therefore, even in case that the light-transmitting ratio of the phase inversion light-transmitting layer 15a increases, the lights transmitting the phase inversion light-transmitting layer 15b are not affected by the light-transmitting ratio of the phase inversion light-transmitting layer 15a. Further, the respective light-transmitting holes 16 of the group pattern hole region G are not affected by the light-transmitting ratio of the phase inversion light-transmitting layer 15a even in case that the phase inversion light-transmitting layer 15 is used as a barrier wall like the isolated light-transmitting hole 20. Finally, a problem that quality of the whole pattern holes may be deteriorated due to increase of unnecessary sidelobe energy can be avoided in advance.

Meanwhile, in another embodiment of the present invention, the finally formed isolated pattern hole H2 undergoes variation in its size depending on variation of the light-transmitting ratio of the phase inversion light-transmitting layer 15a arranged between the respective light-transmitting holes 21, 22, 23 and 24. Based on this fact, in the present invention, the light-transmitting ratio of the phase inversion light-transmitting layer 15a arranged between the respective light-transmitting holes 21, 22, 23 and 24 is flexibly adjusted. Thus, the size of the finally formed isolated pattern hole H2 is flexibly adjusted according to a predetermined design area, thereby allowing the step of forming the whole pattern holes to be efficiently performed.

Hereinafter, a method for fabricating a photo mask according to the other embodiment of the present invention will be described in more detail.

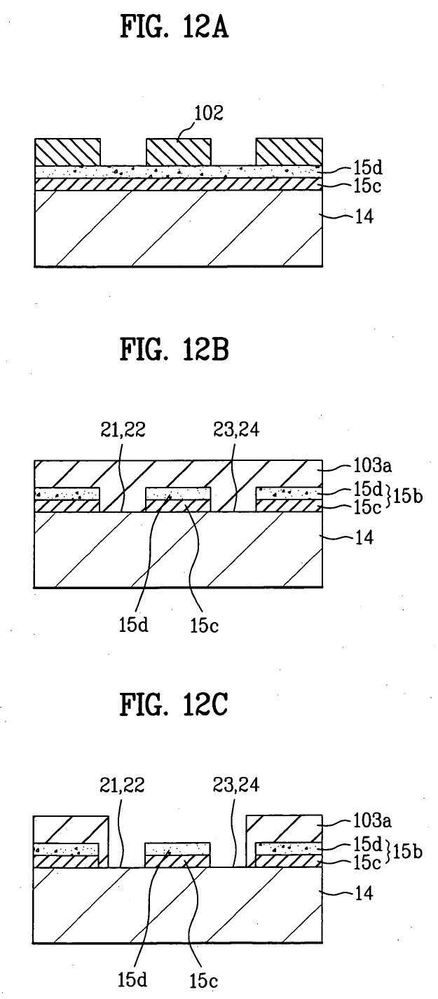

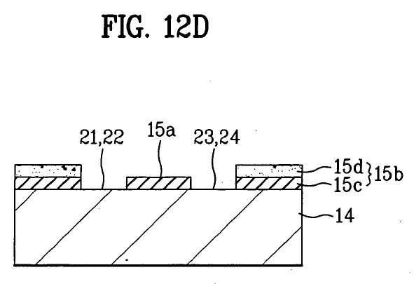

As shown in FIG. 12A, a Cr layer 15c and a MoSiN layer 15d to be used as phase inversion light-transmitting layers are sequentially deposited on a transparent substrate 14 such as a quartz substrate by a chemical vapor deposition process. In this case, it is noted that the MoSiN layer 15d may be replaced with a Si₃N₄ layer or a Cr/SiO₂ layer depending on the circumstances.

Subsequently, a photoresist film is deposited on the Cr layer 15c and the MoSiN layer and then is selectively etched to form a photoresist pattern 102 corresponding to regions for the small sized light-transmitting holes 21, 22, 23 and 24.

Next, the Cr layer 15c and the MoSiN layer 15d are dry-etched using the photoresist pattern 102 as an etching mask to expose some of the surface of the transparent substrate 14. Thus, as shown in FIG. 12B, the small sized light-transmitting holes 21, 22, 23 and 24 aggregated at dense intervals are formed in the isolated pattern hole region I of the phase inversion light-transmitting layer 15. Although not shown, it should be understood that the light-transmitting holes 16 can simultaneously be formed in the group pattern hole region G of the phase inversion light-transmitting layer 15 within the range of the procedure of forming the small sized light-transmitting holes 21, 22, 23 and 24. Then, the photoresist pattern 102 is removed.

Afterwards, a photoresist film 103a is deposited on the semiconductor substrate including the Cr and MoSiN layers 15c and 15d and the light-transmitting holes 21, 22, 23 and 24. The photoresist film 103a is selectively etched to form a photoresist pattern 103. The Cr and MoSiN layers 15c and 15d arranged between the respective light-transmitting holes 21, 22, 23 and 24 are exposed by the photoresist pattern 103.

Subsequently, the Cr layer 15c and the MoSiN layer 15d are selectively removed by a dry etching process using the photoresist pattern 103 as an etching mask.

If the above process steps are finished, as shown in FIG. 12D, the phase inversion light-transmitting layer 15a arranged between the respective light-transmitting holes 21, 22, 23 and 24 has a single layered structure of Cr. Therefore, the phase inversion light-transmitting layer 15a has a light-transmitting ratio greater than that of the phase inversion light-transmitting layer 15b having a multi-layered structure such as Cr/MoSiN. As a result, the sidelobe phenomena can be generated more strongly by the lights which have transmitted the corresponding phase inversion light-transmitting layer 15b.

As aforementioned, the photo mask and the method for fabricating the same have the following advantages.

The transparent substrate is covered with the phase inversion light-transmitting layer, the small sized light-transmitting holes are aggregately formed at dense intervals in the isolated pattern hole region of the phase inversion light-transmitting layer, and lights transmitting the light-transmitting holes and the phase inversion light-transmitting layer are guided to cause a series of interference phenomena such as sidelobe phenomena, so that the isolated pattern hole can receive sufficient light as the light intensity increases by way of the sidelobe phenomena.

In addition, if the sidelobe phenomena conventionally regarded as a defect factor are used to allow an isolated pattern hole to sufficiently receive lights after aggregately forming the small sized light-transmitting holes in the isolated pattern hole region of the transparent substrate, the step of additionally forming serif holes is naturally skipped, thereby improving yield of the product and controlling increase of the production cost.

This application claims the benefit of the Korean patent application No. P2003-101845, filed on Dec. 31, 2003, the entire contents of which is hereby incorporated by reference.

It will be apparent to those skilled in the art that various modifications and variations can be made in the present invention. Thus, it is intended that the present invention covers the modifications and variations of this invention provided they come within the scope of the appended claims and their equivalents.

1. A photo mask comprising:
a transparent substrate;
a phase inversion light-transmitting layer covering an entire surface of the transparent substrate; and
a plurality of small sized light-transmitting holes, each separated from a next closest hole by a predetermined interval and each formed as a separate hole through a predetermined region of the phase inversion light-transmitting layer, wherein
light passing through the plurality of holes cooperates to form a common exposure region to form one feature in a target material, and
light shifted in phase by said phase inversion light-transmitting layer adding in phase with light passing through at least one of said plurality of holes in said common exposure region.

2. The photo mask of claim 1, wherein the phase inversion light-transmitting layer comprises a material that attenuates light passing therethrough by a predetermined amount.

3. The photo mask of claim 1, wherein the phase inversion light-transmitting layer has a light-transmitting ratio of 3% to 12%.

4. The photo mask of claim 1, wherein the phase inversion light-transmitting layer is disposed between the respective plurality of holes so as to separate one hole from another, and a material comprising the phase inversion light-transmitting layer between the respective plurality of holes has a light-transmitting ratio greater than that of the phase inversion light-transmitting layer arranged outside the light-transmitting holes.

5. The photo mask of claim 4, wherein the phase inversion light-transmitting layer disposed between the respective light-transmitting holes has a light-transmitting ratio of 5% to 12% while the phase inversion light-transmitting layer arranged outside the light-transmitting holes has a light-transmitting ratio of 3% to 7%.

6. The photo mask of claim 4, wherein the phase inversion light-transmitting layer arranged between the respective light-transmitting holes includes a single layered structure of Cr while the phase inversion light-transmitting layer arranged outside the light-transmitting holes includes a multi-layered structure selected from any one of Cr/MoSiN, Cr/Si₃N₄, and Cr/SiO₂.

7. The photo mask of claim 1, wherein the light-transmitting holes are separated from a nearest neighboring hole at a single common interval.

8. The photo mask of claim 1, wherein the light-transmitting holes have a size of 0.02 μm to 0.06 μm.

9. A method for fabricating a photo mask comprising:
forming a phase inversion light-transmitting layer on an entire surface of a transparent substrate; and
forming a plurality of small sized light-transmitting holes, each separated from a next closest hole by a predetermined interval and each formed as a separate hole through a predetermined region of the phase inversion light-transmitting layer, wherein
light passing through the plurality of holes cooperates to form a common exposure region to form one feature in a target material, and
light shifted in phase by said phase inversion light-transmitting layer adding in phase with light passing through at least one of said plurality of holes in said common exposure region.

10. A method for fabricating a photo mask comprising:
sequentially depositing first and second phase inversion light-transmitting layers on an entire surface of a transparent substrate;
forming a plurality of small sized light-transmitting holes each separated from a next closest hole by a predetermined interval and each formed as a separate hole through a predetermined region of the phase inversion light-transmitting layers; and
removing the second phase inversion light-transmitting layer arranged between the respective light-transmitting holes.
